(19) United States
(12) Patent Application Publication
(10) Pub. No.: US 2026/0064003 A1
(43) Pub. Date: Mar. 5, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Eunmi KANG, Suwon-si (KR); Minhye KIM, Suwon-si (KR); Kyoungah OH, Suwon-si (KR); Jihyun YOON, Suwon-si (KR); Sukil KANG, Suwon-si (KR); Yaeun SEO, Suwon-si (KR); Minyoung LEE, Suwon-si (KR); Chungheon LEE, Suwon-si (KR); Seongyeon HWANG, Suwon-si (KR); Hujeong YOON, Suwon-si (KR)

(21) Appl. No.: 19/259,799

(22) Filed: Jul. 3, 2025

(30) Foreign Application Priority Data
Aug. 27, 2024 (KR) 10-2024-0115265

(51) Int. Cl. G03F 7/16; G03F 7/004; H01L 21/027

(52) U.S. Cl. CPC G03F 7/16; G03F 7/0042

(57) ABSTRACT

A semiconductor photoresist composition and a method of forming patterns utilizing the semiconductor photoresist composition are disclosed. The semiconductor photoresist composition may include an organometallic compound; a compound represented by Chemical Formula 1; and a solvent. The description of Chemical Formula 1 is as provided in more detail in the present disclosure.

### CROSS-REFERENCE TO RELATED APPLICATION

The present application claims priority to and the benefit of Korean Patent Application No. 10-2024-0115265, filed on Aug. 27, 2024, in the Korean Intellectual Property Office, the entire content of which is incorporated herein by reference.

### BACKGROUND

### 1. Field

One or more embodiments of the present disclosure relate to a semiconductor photoresist composition and a method of forming patterns utilizing the semiconductor photoresist composition.

### 2. Description of the Related Art

Extreme ultraviolet (EUV) lithography has gained attention as an important (e.g., essential) technology for manufacturing a next generation semiconductor device. EUV lithography is a pattern-forming technology that utilizes an EUV ray having a wavelength of 13.5 nm as an exposure light source. In EUV lithography, extremely fine pattern (e.g., less than or equal to 20 nm) may be formed through an exposure process during the manufacturing of semiconductor devices.

The realization of extreme ultraviolet (EUV) lithography depends on development of compatible photoresists that can achieve a spatial resolution of less than or equal to 16 nm. Currently, efforts are underway to address the limitations of chemically amplified (CA) photoresists, such as in resolution, photospeed, and/or feature roughness (also referred to as a line edge roughness or LER), to meet the specifications for the next-generation device.

Intrinsic image blurring due to an acid catalyzed reaction in these polymer-type (kind) photoresists limits a resolution in small feature sizes, a phenomenon known in electron beam (e-beam) lithography for a long time. Chemically amplified (CA) photoresists are designed for high sensitivity, but their typical elemental makeup reduces light absorbance of the photoresists at a wavelength of 13.5 nm, decreasing their sensitivity and making it more difficult to use CA photoresists under EUV exposure.

Also, CA photoresists may have difficulties with small feature sizes due to roughness issues. Experimental results show that line edge roughness (LER) of the CA photoresists increases as photospeed decreases, partially due to inherent characteristics of acid catalyst processes. Therefore, a novel high-performance photoresist is desired or required in the semiconductor industry to address these defects and problems of the CA photoresists.

To overcome the aforementioned drawbacks of CA organic photosensitive compositions, research has been conducted on inorganic photosensitive compositions. These inorganic photosensitive compositions are mainly used for negative tone patterning and have resistance against removal by a developer composition due to chemical modification through a nonchemical amplification mechanism. Inorganic compositions contain inorganic elements with higher EUV absorption rates than hydrocarbons, securing suitable sensitivity through the nonchemical amplification mechanism. Also, inorganic compositions are less sensitive to stochastic effects and may have low line edge roughness and fewer defects.

Inorganic photoresists based on peroxopolyacids of tungsten mixed with tungsten, niobium, titanium, and/or tantalum have been reported as radiation sensitive materials for patterning (see also, U.S. Pat. No. 5,061,599; and H. Okamoto, T. Iwayanagi, K. Mochiji, H. Umezaki, T. Kudo, Applied Physics Letters, 49(5), 298-300, 1986, the entire content of each of which is incorporated herein by reference).

These materials are effective or suitable for patterning large pitches for bilayer configuration as far ultraviolet (deep UV), X-ray, and electron beam sources. More recently, cationic hafnium metal oxide sulfate (HfSOx) materials along with a peroxo complexing agent has been used to image a 15 nm half-pitch (HP) through projection EUV exposure, and impressive performance has been obtained (see also, US 2011-0045406; and J. K. Stowers, A. Telecky, M. Kocsis, B. L. Clark, D. A. Keszler, A. Grenville, C. N. Anderson, P. P. Naulleau, Proc. SPIE, 7969, 796915, 2011, the entire content of each of which is incorporated herein by reference). This system exhibits better performance as a non-CA photoresist and has a practicable photospeed close to the requirement for an EUV photoresist. However, the hafnium metal oxide sulfate material with the peroxo complexing agent has a few practical drawbacks. First, these materials are coated in a mixture of corrosive sulfuric acid/hydrogen peroxide and may have insufficient shelf-life stability. Second, as a composite mixture, structural changes for performance improvement is not easy. Third, development has to be performed in a tetramethylammonium hydroxide (TMAH) solution at a high (e.g., extremely high) concentration of about 25 wt %.

Recently, active research has been conducted on molecules including tin (e.g., tin-containing materials), which have excellent or suitable absorption of extreme ultraviolet rays. Among these, organic tin (e.g., organotin) polymers dissociate alkyl ligands by light absorption or secondary electrons, and crosslink with adjacent chains through oxo bonds to enable negative tone patterning that resists removal by an organic developer. This organic tin polymer exhibits greatly improved or enhanced sensitivity while maintaining suitable resolution and line edge roughness, but the patterning characteristics need further improvement or enhancement for commercial applications.

### SUMMARY

One or more aspects of embodiments of the present disclosure are directed toward a semiconductor photoresist composition with enhanced (e.g., excellent or suitable) coating properties and enhanced (e.g., improved) sensitivity.

One or more aspects of embodiments of the present disclosure are directed toward a method of forming patterns utilizing the semiconductor photoresist composition.

Additional aspects of embodiments will be set forth in part in the description which follows and, in part, will be apparent from the description or may be learned by practice of the presented embodiments of the disclosure.

A semiconductor photoresist composition according to one or more embodiments includes an organometallic compound; a compound represented by Chemical Formula 1; and a solvent.

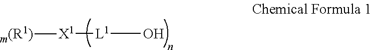

In Chemical Formula 1,
R¹ is hydrogen, a substituted or unsubstituted C1 to C20 alkyl group, a substituted or unsubstituted C3 to C20 cycloalkyl group, a substituted or unsubstituted C6 to C20 aryl group, a substituted or unsubstituted C7 to C20 arylalkyl group, and/or a (e.g., any suitable) combination thereof,
X¹ is a heteroatom having a valence of 2 to 5,
L¹ is a substituted or unsubstituted C1 to C10 alkylene group,
m is an integer of 0 to 3,
n is an integer of greater than or equal to 2, and
m+n is an integer of 2 to 5.

A method of forming patterns according to one or more embodiments includes forming or applying an etching-objective layer on a substrate, coating the semiconductor photoresist composition on the etching-objective layer to form a photoresist film, patterning the photoresist film to form a photoresist pattern, and etching the etching-objective layer utilizing the photoresist pattern as an etching mask.

The semiconductor photoresist composition according to one or more embodiments may provide a photoresist pattern with improved or enhanced coating properties, storage stability, and LER characteristics. For example, the enhanced coating properties may ensure a uniform (e.g., substantially uniform) and defect-free (e.g., substantially defect-free) photoresist layer, which is important to achieve high-resolution patterns. Improved or enhanced storage stability refers to that the photoresist composition maintains its performance characteristics over extended periods, reducing the risk of degradation or contamination. Enhanced LER characteristics may result in smoother and more precise pattern edges, which are important for the fabrication of advanced semiconductor devices with smaller feature sizes. These improvements or enhancements may collectively contribute to higher yield and reliability in semiconductor manufacturing processes.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1E are cross-sectional views illustrating a method of forming patterns by utilizing a semiconductor photoresist composition according to one or more embodiments.

### DETAILED DESCRIPTION

Hereinafter, referring to the drawings, embodiments of the present disclosure are described in more detail. In the following description of the present disclosure, one or more functions or constructions that are generally recognized by a person having ordinary skill in the art may not be described in order to clarify the present disclosure.

Like reference numerals designate like elements throughout, and duplicative descriptions thereof may not be provided in the specification.

As used herein, the singular forms “a,” “an,” and “the” are intended to include the plural forms as well, unless the context clearly indicates otherwise. The singular expression includes the plural expression unless the context clearly dictates otherwise.

As used herein, “combination thereof” refers to a mixture, a laminate, a composite, a copolymer, an alloy, a blend, a reaction product, and/or the like of the constituents.

In order to clearly illustrate one or more embodiments of the present disclosure, the description and relationships may not be provided, and throughout the present disclosure, substantially the same or similar configuration (or arrangement) elements are designated by the same reference numerals. Also, because the size and thickness of each configuration or arrangement as shown in the drawing may be arbitrarily shown for better understanding and ease of description, embodiments of the present disclosure are not necessarily limited thereto.

As used herein, the term “and/or” or “or” includes any and all combinations of one or more of the associated listed items. Throughout the present disclosure, the expressions such as “at least one of,” “one of,” and “selected from,” if (e.g., when) preceding a list of elements, modify the entire list of elements and do not modify the individual elements of the list. For example, “at least one of a, b, or c,” “at least one selected from a, b, and c,” or “at least one selected from among a to c”, and/or the like indicates only a, only b, only c, both (e.g., simultaneously) a and b, both (e.g., simultaneously) a and c, both (e.g., simultaneously) b and c, all of a, b, and c, or variations thereof.

The utilization of “may” if (e.g., when) describing embodiments of the present disclosure refers to “one or more embodiments of the present disclosure.”

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

In the drawings, the thickness of layers, films, panels, regions, and/or the like may be exaggerated for clarity. In the drawings, the thickness of a part of layers, films, panels, regions, and/or the like may be exaggerated for clarity.

It will be understood that if (e.g., when) an element, such as a layer, a film, a region, or a substrate is referred to as being “on” another element, it may be directly on the other element or intervening elements may also be present therebetween. In contrast, if (e.g., when) an element is referred to as being “directly on” another element, there may be no intervening elements present therebetween.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations, or within ±30%, ±20%, ±10%, or ±5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

As used herein, “substituted” refers to replacement of a hydrogen atom by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, and/or a (e.g., any suitable) combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group or a C3 to C6 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, “aryl group” refers to a substituent in which all atoms in the cyclic substituent have a p-orbital and these p-orbitals are conjugated and may include a monocyclic, polycyclic or fused ring (e.g., rings sharing adjacent pairs of carbon atoms) functional group.

Unless otherwise defined, all terms (including technical and scientific terms) used herein have substantially the same meaning as generally understood by one of ordinary skill in the art to which the present disclosure belongs. It will be further understood that terms, such as those defined in dictionaries that are generally available or generally used, should be interpreted as having a meaning that is consistent with their meaning in the context of the relevant art and will not be interpreted in an idealized or overly formal sense unless expressly so defined herein.

Hereinafter, a semiconductor photoresist composition according to one or more embodiments is described in more detail.

The semiconductor photoresist composition according to one or more embodiments may include an organometallic compound, a compound represented by Chemical Formula 1, and a solvent.

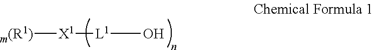

In Chemical Formula 1,
R¹ may be hydrogen, a substituted or unsubstituted C1 to C20 alkyl group, a substituted or unsubstituted C3 to C20 cycloalkyl group, a substituted or unsubstituted C6 to C20 aryl group, a substituted or unsubstituted C7 to C20 arylalkyl group, and/or a (e.g., any suitable) combination thereof,
X¹ may be a heteroatom having a valence of 2 to 5,
L¹ may be a substituted or unsubstituted C1 to C10 alkylene group,
m may be an integer of 0 to 3,
n may be an integer of greater than or equal to 2, and
m+n may be an integer of 2 to 5.

The compound represented by Chemical Formula 1 included in the semiconductor photoresist composition according to one or more embodiments may include both (e.g., simultaneously) alcohol (e.g., hydroxyl group) and a heteroatom. The alcohol functional group (e.g., hydroxyl group) has a good or suitable affinity for inorganic elements, such as tin, which promotes or enhances intermolecular bonding after exposure, and thus improves or enhances sensitivity.

In one or more embodiments, the unshared electron pair of the alcohol (e.g., hydroxyl group) that is not used for bonding may increase the adsorption to the substrate, thereby improving or enhancing the surface coating property.

For example, X¹ may be selected from among nitrogen (N), oxygen (O), sulfur (S), and phosphorus (P).

For example, X¹ may be selected from among N, O, and S.

For example, X¹ may be N or S.

For example, L¹ may be a substituted or unsubstituted C1 to C6 alkylene group.

For example, R¹ may be hydrogen, a substituted or unsubstituted C1 to C10 alkyl group, a substituted or unsubstituted C5 to C20 cycloalkyl group, or a substituted or unsubstituted C6 to C12 aryl group.

In one or more embodiments, Chemical Formula 1 may be selected from among Chemical Formula 1-1 to Chemical Formula 1-4.

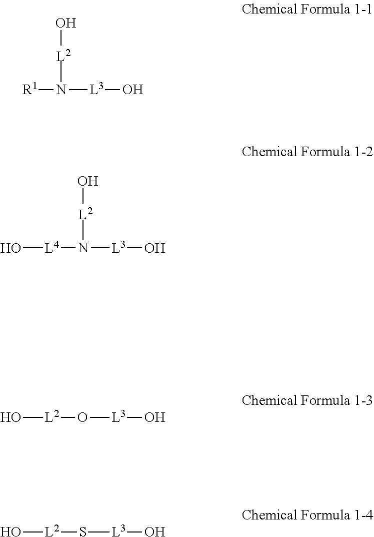

In Chemical Formula 1-1 to Chemical Formula 1-4,
R¹ may be hydrogen, a substituted or unsubstituted C1 to C20 alkyl group, a substituted or unsubstituted C6 to C20 aryl group, and/or a (e.g., any suitable) combination thereof, and
L² to L⁴ may each independently be a substituted or unsubstituted C1 to C10 alkylene group.

For example, the compound represented by Chemical Formula 1 may be selected from among the compounds listed in Group 1.

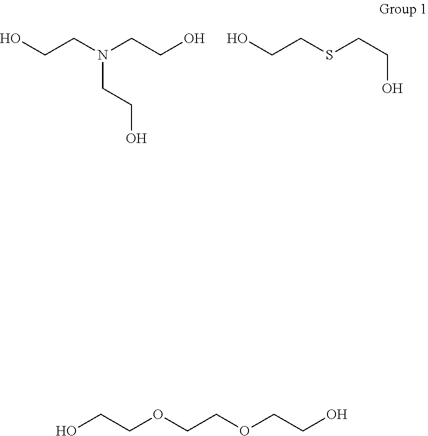 [SMILES: OCCN(CCO)CCO ; OCCSCCO ; OCCOCCOCCO]

The compound represented by Chemical Formula 1 may be included in an amount of about 0.001 wt % to about 5 wt % based on 100 wt % of the semiconductor photoresist composition.

For example, the compound represented by Chemical Formula 1 may be included in an amount of about 0.005 wt % to about 5 wt %, about 0.01 wt % to about 5 wt %, or about 0.03 wt % to about 5 wt % based on 100 wt % of the semiconductor photoresist composition.

The organometallic compound may be included in an amount of about 0.5 wt % to about 30 wt % based on 100 wt % of the semiconductor photoresist composition.

The semiconductor photoresist composition according to one or more embodiments may improve or enhance the sensitivity of the photoresist by including the compound represented by Chemical Formula 1 in the foregoing content (e.g., amount) range.

The organometallic compound may be an organotin compound including at least one selected from among an organic oxy group and an organic carbonyloxy group.

For example, the organometallic compound may be represented by Chemical Formula 2.

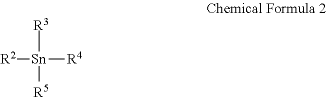

In Chemical Formula 2,
R² may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R³ to R⁵ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (—NR^{h}C(NRⁱ)Rⁱ, wherein R^{h}, Rⁱ, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof),
at least one selected from among R³ to R⁵ may be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (—NR^{h}C(NRⁱ)Rⁱ, wherein R^{h}, Rⁱ, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

At least one selected from among R³ to R⁵ may be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof) and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

In one or more embodiments, because the compound represented by Chemical Formula 2 includes —OR^{b} or —OC(═O)R^{c} as a ligand, a pattern formed using a semiconductor photoresist composition including the compound may exhibit excellent or suitable limit resolution.

In one or more embodiments, the ligand of —OR^{b} or —OC(═O)R^{c} may determine the solubility of the compound represented by Chemical Formula 2 in a solvent.

R² may be a substituted or unsubstituted C1 to C8 alkyl group, a substituted or unsubstituted C3 to C8 cycloalkyl group, a substituted or unsubstituted C2 to C8 unsaturated aliphatic group (e.g., unsaturated hydrocarbons) including one or more double bonds and/or triple bonds, a substituted or unsubstituted C6 to C20 aryl group, a substituted or unsubstituted C4 to C20 heteroaryl group, a carbonyl group, an ethoxy group, a propoxy group, and/or a (e.g., any suitable) combination thereof,

R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and/or a (e.g., any suitable) combination thereof, and

R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and/or a (e.g., any suitable) combination thereof.

R² may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, and/or a (e.g., any suitable) combination thereof,

R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, and/or a (e.g., any suitable) combination thereof, and

R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, and/or a (e.g., any suitable) combination thereof.

In one or more embodiments, the organometallic compound may be represented by Chemical Formula 3 or Chemical Formula 4.

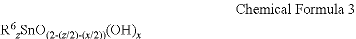

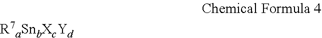

wherein, in Chemical Formula 4,
R⁷ may be a substituted or unsubstituted C1 to C20 alkyl group, a substituted or unsubstituted C3 to C20 cycloalkyl group, a substituted or unsubstituted C2 to C20 unsaturated aliphatic group (e.g., unsaturated hydrocarbons) including one or more double bonds and/or triple bonds, a substituted or unsubstituted C6 to C30 aryl group, a substituted or unsubstituted C4 to C30 heteroaryl group, a carbonyl group, an ethylene oxide group, a propylene oxide group, and/or a (e.g., any suitable) combination thereof,
X may be sulfur (S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof,
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof, and
a, b, c, and d may each independently be an integer of 1 to 20.

The solvent included in the semiconductor photoresist composition according to one or more embodiments may be an organic solvent, and may be, for example, aromatic compounds (e.g., xylene, toluene, and/or the like.), alcohols (e.g., 4-methyl-2-pentanol, 4-methyl-2-propanol, 1-butanol, methanol, isopropyl alcohol, 1-propanol, and/or the like), ethers (e.g., anisole, tetrahydrofuran, and/or the like), esters (n-butyl acetate, propylene glycol monomethyl ether acetate, ethyl acetate, ethyl lactate, and/or the like), ketones (e.g., methyl ethyl ketone, 2-heptanone, and/or the like), and/or a (e.g., any suitable) mixture thereof, but embodiments of the present disclosure are not limited thereto.

The semiconductor photoresist composition according to one or more embodiments may further include a resin in addition to the organometallic compound, the compound represented by Chemical Formula 1, and the solvent as described in one or more embodiments.

The resin may be a phenol-based resin including at least one aromatic moiety listed (e.g., at least one selected from among those) in Group 2.

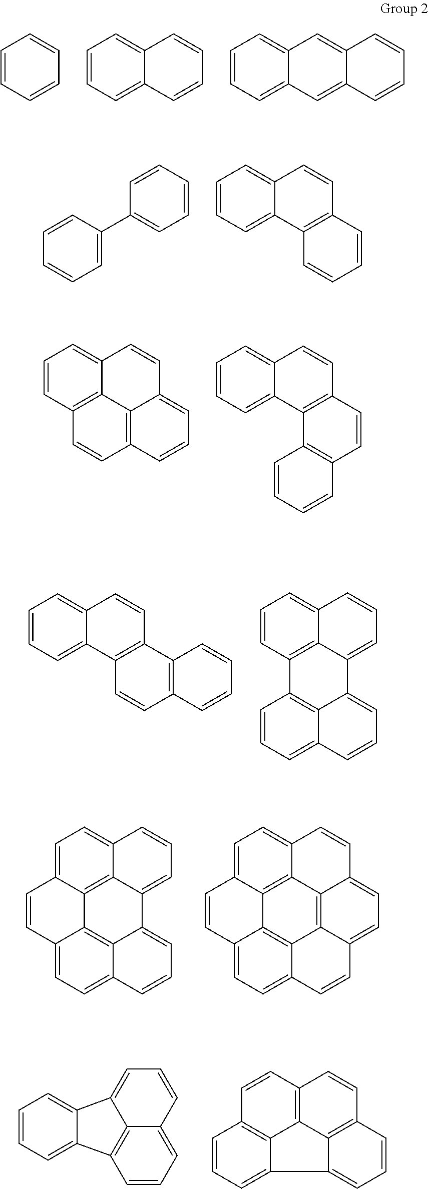

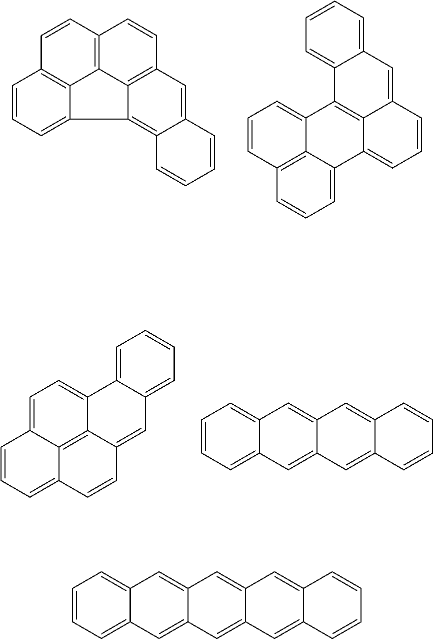

The resin may have a weight average molecular weight of about 500 g/mol to about 20,000 g/mol.

The resin may be included in an amount of about 0.1 wt % to about 50 wt % based on a total amount (e.g., based on 100 wt %) of the semiconductor photoresist composition.

If (e.g., when) the resin as described in one or more embodiments is included within the foregoing content (e.g., amount) range, excellent or suitable etching resistance and heat resistance may be achieved.

In one or more embodiments, it is desirable that the semiconductor photoresist composition is composed of (e.g., includes) the organometallic compound, the compound represented by Chemical Formula 1, the solvent, and the resin as described in one or more embodiments.

However, the semiconductor photoresist composition according to one or more embodiments may further include additives as desired or needed. Examples of the additives may be a surfactant, a crosslinking agent, a leveling agent, an organic acid, a quencher, and/or a (e.g., any suitable) combination thereof.

The surfactant may include, for example, an alkyl benzene sulfonate salt, an alkyl pyridinium salt, polyethylene glycol, a quaternary ammonium salt, and/or a (e.g., any suitable) combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, and/or a polymer-based crosslinking agent, but embodiments of the present disclosure are not limited thereto. It may be a crosslinking agent having at least two crosslinking forming substituents, for example, a compound, such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used to improve or enhance coating flatness during printing and may be a leveling agent that is generally available or generally used.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a (e.g., any suitable) combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, and/or a (e.g., any suitable) combination thereof.

A use amount of the additives may be controlled or selected depending on desired or suitable properties.

In one or more embodiments, the semiconductor photoresist composition may further include a silane coupling agent as an adherence enhancer in order to improve or enhance a close-contacting force with the substrate (e.g., in order to improve or enhance adherence of the semiconductor photoresist composition to the substrate). The silane coupling agent may be, for example, a silane compound including a carbon-carbon unsaturated bond, such as vinyltrimethoxysilane, vinyl triethoxysilane, vinyl trichlorosilane, vinyl tris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane, trimethoxy[3-(phenylamino)propyl]silane, and/or the like, but embodiments of the present disclosure are not limited thereto.

The semiconductor photoresist composition may be formed into a pattern having a high aspect ratio without a collapse. Accordingly, in order to form a fine pattern having a width of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be used to realize extreme ultraviolet lithography using an EUV light source of a wavelength of about 13.5 nm.

According to one or more embodiments, a method of forming patterns using the semiconductor photoresist composition as described in one or more embodiments is provided. For example, the manufactured pattern may be a photoresist pattern.

The method of forming patterns according to one or more embodiments may include forming or applying an etching-objective layer on a substrate, coating the semiconductor photoresist composition on the etching-objective layer to form a photoresist film, patterning the photoresist film to form a photoresist pattern, and etching the etching-objective layer utilizing the photoresist pattern as an etching mask.

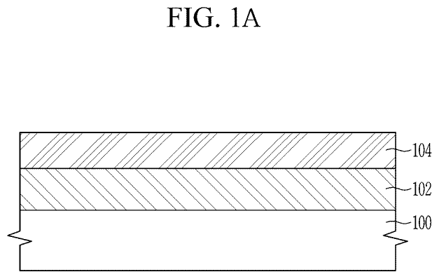

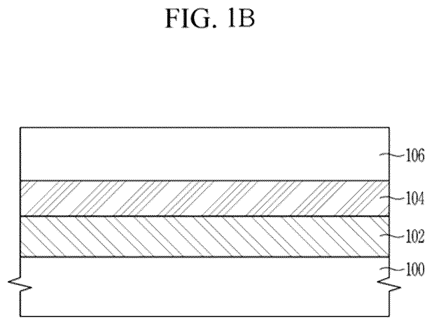

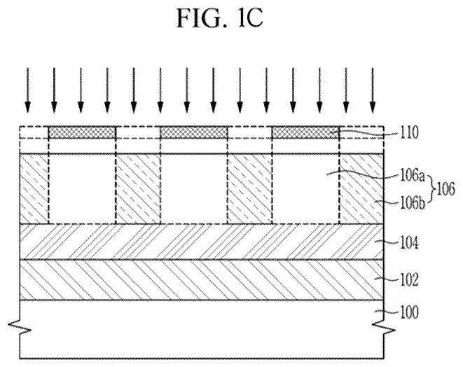

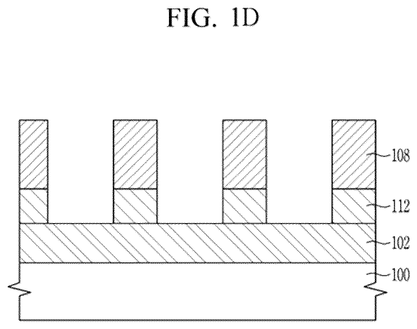

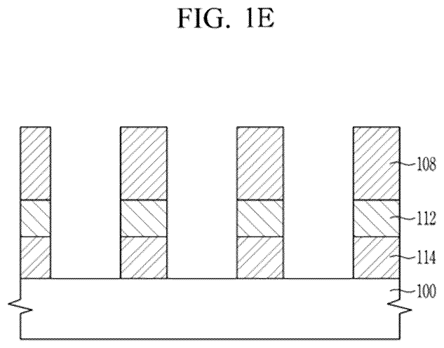

Hereinafter, a method of forming patterns using the semiconductor photoresist composition is described in more detail referring to FIGS. 1A to 1E. FIGS. 1A to 1E are cross-sectional views illustrating a method of forming patterns using a semiconductor photoresist composition according to one or more embodiments.

Referring to FIG. 1A, an object for etching may be prepared. The object for etching may be a thin film 102 formed or applied on a semiconductor substrate 100. Hereinafter, the object for etching may be limited to the thin film 102. A surface of the thin film 102 may be washed to remove impurities and/or the like that remain thereon. The thin film 102 may be, for example, a silicon nitride layer, a polysilicon layer, and/or a silicon oxide layer.

Subsequently, the resist underlayer composition to form a resist underlayer 104 may be spin-coated on the surface of the washed thin film 102. However, embodiments of the present disclosure are not limited thereto, and one or more suitable coating methods, for example, a spray coating, a dip coating, a knife edge coating, a printing method, for example, an inkjet printing and/or a screen printing, and/or the like, may be used.

The coating process of the resist underlayer may not be provided, and hereinafter, a process including a coating of the resist underlayer is described in more detail.

Then, the coated composition may be dried and baked (heat treated) to form or apply a resist underlayer 104 on the thin film 102. The baking may be performed at about 100° C. to about 500° C., for example, about 100° C. to about 300° C.

The resist underlayer 104 may be formed between the substrate 100 and a photoresist film 106 and thus may prevent or reduce non-uniformity and pattern formability of a photoresist line width if (e.g., when) a ray reflected from on the interface between the substrate 100 and the photoresist film 106 or a hardmask between layers is scattered into an unintended photoresist region.

Referring to FIG. 1B, the photoresist film 106 may be formed by coating the semiconductor photoresist composition on the resist underlayer 104. The photoresist film 106 may be obtained by coating the semiconductor photoresist composition as described in one or more embodiments on the thin film 102 formed or coated on the substrate 100 and then, curing it through a heat treatment.

For example, the formation of a pattern by using the semiconductor photoresist composition may include coating the semiconductor resist composition on the substrate 100 having the thin film 102 through spin coating, slit coating, inkjet printing, and/or the like and then, drying it to form the photoresist film 106.

The semiconductor photoresist composition has already been illustrated in more detail and may not be illustrated again.

Subsequently, a substrate 100 having the photoresist film 106 may be subjected to a first baking process. The first baking process may be performed at about 80° C. to about 120° C.

Referring to FIG. 1C, the photoresist film 106 may be selectively exposed using a patterned mask 110.

For example, the exposure may use activation radiation with light having a relatively high-energy wavelength, such as extreme ultraviolet (EUV) light with a wavelength of about 13.5 nm, an electron beam (E-Beam), and/or similar sources. In one or more embodiments, the exposure may use light having relatively low-energy wavelengths, such as i-line (about 365 nm), KrF excimer laser (about 248 nm), ArF excimer laser (about 193 nm), and/or similar sources.

For example, light for the exposure according to one or more embodiments may have a wavelength in a range of about 5 nm to about 150 nm. This may include relatively high-energy wavelengths, such as extreme ultraviolet (EUV) light with a wavelength of about 13.5 nm, and other sources, such as an electron beam (E-Beam).

The exposed region 106b of the photoresist film 106 may have a different solubility from the unexposed region 106a of the photoresist film 106 by forming or applying a polymer by a crosslinking reaction, such as condensation between organometallic compounds.

Subsequently, the substrate 100 may be subjected to a second baking process. The second baking process may be performed at a temperature of about 90° C. to about 200° C. The exposed region 106b of the photoresist film 106 may become relatively easily indissoluble with respect to a developer due to the second baking process.

In FIG. 1D, the unexposed region 106a of the photoresist film may be dissolved and removed using the developer to form a photoresist pattern 108. For example, the unexposed region 106a of the photoresist film may be dissolved and removed by using an organic solvent, such as 2-heptanone and/or the like, to complete the photoresist pattern 108 that corresponds to the negative tone image.

As described in one or more embodiments, a developer used in a method of forming patterns according to one or more embodiments may be an organic solvent. The organic solvent used in the method of forming patterns according to one or more embodiments may be, for example, ketones, such as methylethylketone, acetone, cyclohexanone, 2-heptanone, and/or the like, alcohols, such as 4-methyl-2-propanol, 1-butanol, isopropanol, 1-propanol, methanol, and/or the like, esters, such as propylene glycol monomethyl ether acetate, ethyl acetate, ethyl lactate, n-butyl acetate, butyrolactone, and/or the like, aromatic compounds, such as benzene, xylene, toluene, and/or the like, and/or a (e.g., any suitable) combination thereof.

However, the photoresist pattern according to one or more embodiments is not necessarily limited to the negative tone image but may be formed to have a positive tone image. Herein, a developer used to form the positive tone image may be a quaternary ammonium hydroxide composition, such as tetraethylammonium hydroxide, tetrapropylammonium hydroxide, tetrabutylammonium hydroxide, and/or a (e.g., any suitable) combination thereof.

As described in one or more embodiments, exposure to light having a relatively high energy wavelength, such as EUV (extreme ultraviolet; a wavelength of about 13.5 nm), an E-Beam (an electron beam), and/or the like, as well as light having a relatively low energy wavelength, such as i-line (wavelength of about 365 nm), KrF excimer laser (wavelength of about 248 nm), ArF excimer laser (wavelength of about 193 nm), and/or the like, may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In contrast, the photoresist pattern 108 may have a pitch having a half-pitch of less than or equal to about 50 nm, for example, less than or equal to about 40 nm, for example, less than or equal to about 30 nm, for example, less than or equal to about 20 nm, or, for example, less than or equal to about 15 nm, and a line width roughness of less than or equal to about 10 nm, or less than or equal to about 5 nm, less than or equal to about 3 nm, or less than or equal to about 2 nm.

Subsequently, the photoresist pattern 108 may be used as an etching mask to etch the resist underlayer 104. Through this etching process, an organic film pattern 112 may be formed. The organic film pattern 112 also may have a width that corresponds to that of the photoresist pattern 108.

Referring to FIG. 1E, the exposed thin film 102 may be etched by applying the photoresist pattern 108 as an etching mask. As a result, the thin film may be formed as a thin film pattern 114.

The etching of the thin film 102 may be, for example, dry etching using an etching gas, and the etching gas may be, for example, CHF₃, CF₄, Cl₂, BCl₃, and/or a (e.g., any suitable) mixed gas thereof.

In the exposure process, the thin film pattern 114 formed by using the photoresist pattern 108 formed through the exposure process performed by using an EUV light source may have a width that corresponds to that of the photoresist pattern 108. For example, the thin film pattern 114 may have a width of about 5 nm to about 100 nm which is substantially equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width of less than or equal to about 20 nm, which is substantially equal to that of the photoresist pattern 108.

Hereinafter, one or more embodiments of the present disclosure will be described in more detail through examples of the preparation of the semiconductor photoresist composition as described in one or more embodiments. However, embodiments of the present disclosure are technically not restricted by the following examples.

### Synthesis of Organometallic Compound

### Synthesis Example 1

40.7 g of t-butylSnPh3 and 300 g of propionic acid were added to a 250 mL 2-necked round-bottomed flask and then, refluxed by heating for 24 hours. A compound represented by Chemical Formula 5 was obtained by removing the unreacted propionic acid under a reduced pressure therefrom.

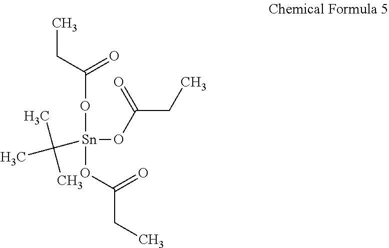 [SMILES: CCC(=O)[O][Sn]([O]C(=O)CC)([O]C(=O)CC)[C](C)(C)C]

### Synthesis Example 2

After adding 30 mL of anhydrous pentane to 10 g of t-AmylSnCl₃ and maintaining their temperature at 0° C., 7.4 g of diethyl amine and 6.1 g of ethanol were added thereto and then, stirred at room temperature for 1 hour. When a reaction was completed, the resultant was filtered, concentrated, and vacuum-dried, obtaining a compound represented by Chemical Formula 6.

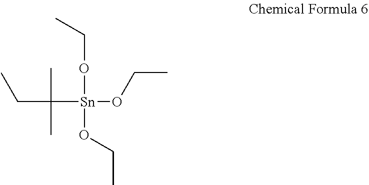

### Synthesis Example 3

10 g of dibutyltin dichloride was dissolved 30 mL of diethyl ether, 70 mL of a 1 M sodium hydroxide (NaOH) aqueous solution was added thereto and then, stirred for 1 hour. After the stirring, a solid produced therein was filtered, three times washed with 25 mL of deionized water, and dried at 100° C. under a reduced pressure to obtain an organometallic compound represented by Chemical Formula 7 and having a weight average molecular weight of 1,500 g/mol.

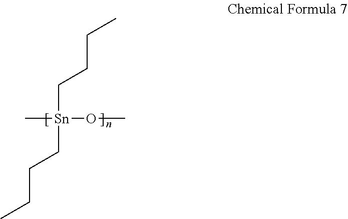

### Preparation of Semiconductor Photoresist Compositions

### Examples 1 to 6 and Comparative Examples 1 and 2

The organometallic compounds obtained in Synthesis Examples 1 to 3 were each dissolved in propylene glycol methyl ether acetate (PGMEA) at a concentration of 3%, and alcohol compounds C1 to C3 were added at the concentrations listed in Table 1 and dissolved, and then filtered through a 0.1 μm polytetrafluoroethylene (PTFE) syringe filter to prepare semiconductor photoresist compositions according to Examples and Comparative Examples. Each composition was coated on a silicon wafer to a thickness of 240 Å, and then a patterned film was manufactured through post-apply bake (PAB), exposure, post-exposure bake (PEB), and development processes.

TABLE 1

| | Organometallic compound | Alcohol compound |
|---|---|---|
| | (wt %) | (wt %) |
| Comparative Example 1 | Chemical Formula 5 | — |
| | (3) | |
| Comparative Example 2 | Chemical Formula 5 | C3 |
| | (2.5) | (0.5) |
| Example 1 | Chemical Formula 5 | C1 |
| | (2.5) | (0.5) |
| Example 2 | | C2 |
| | | (0.5) |
| Example 3 | Chemical Formula 5 | C1 |
| | (2.7) | (0.3) |
| Example 4 | Chemial Formula 5 | C1 |
| | (2.9) | (0.1) |
| Example 5 | Chemical Formula 6 | C1 |
| | (3) | (0.5) |
| Example 6 | Chemical Formula 7 | C1 |
| | (3) | (0.5) |

C1: 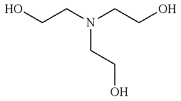
C2: 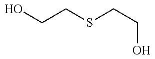
C3:

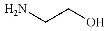

### Evaluation 1: Sensitivity Evaluation

Each of the photoresist compositions according to Examples and Comparative Examples was spin-coated for 30 seconds at 1500 rpm, respectively, on a 200 mm circular silicon wafer whose surface was deposited with hexamethyldisilazane (HMDS), and baked at 110° C. for 60 seconds. After application, it was baked (post-apply bake, PAB) and then left at room temperature (23±2° C.) for 30 seconds.

Afterwards, a linear array with a width of 50 nm was projected onto the wafer coated with the photoresist composition using EUV light (Lawrence Berkeley National Laboratory Micro Exposure Tool, MET). Pad exposure time was adjusted to ensure that the EUV light in an increased dose was applied to each pad.

Then, the resist and the substrate were baked at 160° C. for 120 seconds on a hot plate after the exposure. The baked film was developed with a PGMEA solvent to form a negative tone image. Finally, the obtained film was baked again at 150° C. for 2 minutes on the hot plate, completing the process.

Resist line width was measured for changes in expose dose (energy) using critical dimension-scanning electron microscope (CD-SEM). The sensitivity to the exposure amount was confirmed from the resist line width values formed differently according to each exposure dose, and the sensitivity and LER were evaluated according to the following criteria, and the results are shown in Table 2.

### Sensitivity Evaluation Criteria

A: less than 16 mJ/cm²

B: greater than or equal to 16 mJ/cm² and less than 18 mJ/cm²

C: greater than or equal to 18 mJ/cm²

### Evaluation 2: Evaluation of Coating Performance

The photoresist compositions according to Examples 1 to 6 and Comparative Examples 1 and 2 were spin-coated on the wafer at 1500 rpm for 60 seconds and baked at 110° C. for 60 seconds to form thin films. The surface roughness of the thin films was measured according to the following standards using software (e.g., optical profiler) from images taken with an atomic force microscope (AFM) and/or the like, and the results are shown in Table 2.

Among surface roughness, average roughness (R_{q}; root mean square roughness) refers to the average square root (rms) of the square of the vertical value within the reference length of the roughness profile.

### Evaluation Criteria

⊚: R_{q} is less than or equal to 0.3 nm.

∘: R_{q} is greater than 0.3 nm and less than or equal to 0.4 nm.

X: R_{q} is greater than 0.4 nm.

TABLE 2

| | Sensitivity | Coating properties (R_{q}) |
|---|---|---|
| Comparative Example 1 | C | X |
| Comparative Example 2 | C | ◯ |
| Example 1 | A | ⊚ |
| Example 2 | A | ⊚ |
| Example 3 | A | ◯ |
| Example 4 | B | ⊚ |
| Example 5 | B | ⊚ |
| Example 6 | B | ◯ |

From the results in Table 2, the semiconductor photoresist compositions according to Examples 1 to 6 exhibit superior sensitivity and coating properties compared to Comparative Examples 1 and 2. For example, the compositions in Examples 1 to 6 demonstrate a higher sensitivity, as indicated by their ability to form clear and precise patterns at lower exposure doses (less than 16 mJ/cm² for Examples 1 to 3 and between 16 to 18 mJ/cm² for Examples 4 to 6). This high sensitivity is important or desirable for advanced lithography processes, as it allows for the creation of fine features with reduced energy input, thereby enhancing efficiency and reducing costs.

Also, the coating properties of the compositions in Examples 1 to 6 are significantly better, with average roughness (R_{q}) values of less than or equal to 0.3 nm (⊚) or between 0.3 nm and 0.4 nm (∘). This indicates a smoother and more uniform photoresist layer, which is important or desirable for achieving high-resolution patterns and minimizing or reducing defects. The improved or enhanced coating properties contribute to the overall reliability and performance of the semiconductor devices manufactured using these photoresist compositions.

In contrast, the Comparative Examples 1 and 2 show lower sensitivity and poorer coating properties, with higher R_{q} values indicating rougher surfaces. These results highlight the advantages of the organometallic compounds and formulations used in the Examples, which provide enhanced performance characteristics for semiconductor manufacturing.

The superior performance of the Examples may be attributed to the specific organometallic compounds and the precise formulation process. For instance, Example 1 uses Chemical Formula 5 combined with alcohol compound C1, resulting in a composition that balances sensitivity and coating properties. Example 5, which uses Chemical Formula 6, demonstrates the versatility of different organometallic compounds in achieving high performance. Example 6, utilizing Chemical Formula 7, showcases the effectiveness or suitability of a compound with a higher molecular weight in providing excellent or suitable coating properties and sensitivity.

A person of ordinary skill in the art would appreciate, in view of the present disclosure in its entirety, that each suitable feature of the one or more embodiments of the present disclosure may be combined or combined with one another, partially or entirely, and may be technically interlocked and operated in one or more suitable ways, and each embodiment may be implemented independently of one another or in conjunction with one another in any suitable manner unless otherwise stated or implied.

A device of forming patterns or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the one or more suitable components of the device may be formed on one integrated circuit (IC) chip or on separate IC chips. Further, the one or more suitable components of the device may be implemented on a flexible printed circuit film, a tape carrier package (TCP), a printed circuit board (PCB), or formed on one substrate.

Further, the one or more suitable components of the device may be a process or thread, running on one or more processors, in one or more computing devices, executing computer program instructions and interacting with other system components for performing the one or more suitable functionalities as described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

Hereinbefore, certain embodiments of the present disclosure have been described and illustrated, however, it should be apparent to a person having ordinary skill in the art that the present disclosure is not limited to the embodiments as described and may be suitably modified and transformed without departing from the spirit and scope of the present disclosure. Accordingly, the modified or transformed embodiments as such may not be understood separately from the technical ideas and aspects of one or more embodiments of the present disclosure, and the modified embodiments may be within the scope of the appended claims and equivalents thereof of the present disclosure.

### REFERENCE NUMERALS

| | |
|---|---|
| 100: substrate | 102: thin film |
| 104: resist underlayer | 106 photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising:
an organometallic compound;
a compound represented by Chemical Formula 1; and
a solvent: 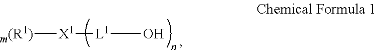
wherein, in Chemical Formula 1,
R¹ is hydrogen, a substituted or unsubstituted C1 to C20 alkyl group, a substituted or unsubstituted C3 to C20 cycloalkyl group, a substituted or unsubstituted C6 to C20 aryl group, a substituted or unsubstituted C7 to C20 arylalkyl group, or a combination thereof,
X¹ is a heteroatom having a valence of 2 to 5,
L¹ is a substituted or unsubstituted C1 to C10 alkylene group,
m is an integer of 0 to 3,
n is an integer of greater than or equal to 2, and
m+n is an integer of 2 to 5.

2. The semiconductor photoresist composition as claimed in claim 1, wherein:
X¹ comprises one selected from among N, O, S, and P.

3. The semiconductor photoresist composition as claimed in claim 1, wherein:
X¹ comprises one selected from among N, O, and S.

4. The semiconductor photoresist composition as claimed in claim 1, wherein:
Chemical Formula 1 is selected from among Chemical Formula 1-1 to Chemical Formula 1-4: 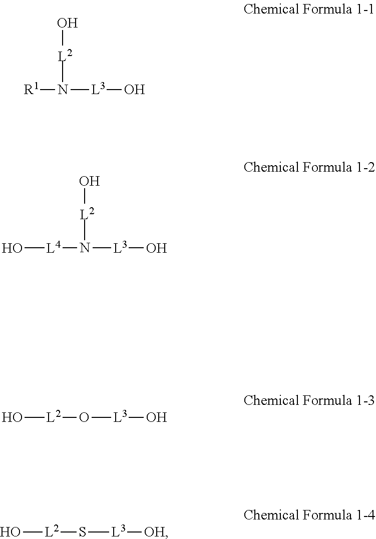
and
wherein, in Chemical Formula 1-1 to Chemical Formula 1-4,
R¹ is hydrogen, a substituted or unsubstituted C1 to C20 alkyl group, a substituted or unsubstituted C6 to C20 aryl group, or a combination thereof, and
L² to L⁴ are each independently a substituted or unsubstituted C1 to C10 alkylene group.

5. The semiconductor photoresist composition as claimed in claim 1, wherein:
the compound represented by Chemical Formula 1 is one selected from among the compounds listed in Group 1:

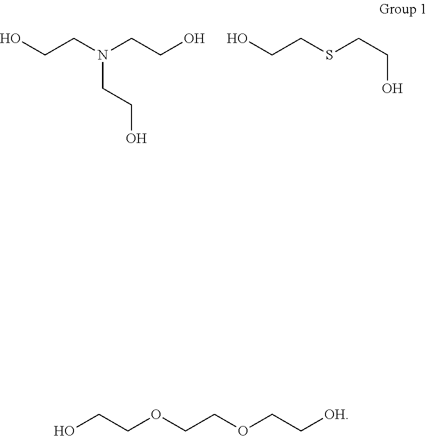 [SMILES: OCCN(CCO)CCO ; OCCSCCO ; OCCOCCOCCO]

6. The semiconductor photoresist composition as claimed in claim 1, wherein:
the compound represented by Chemical Formula 1 is in an amount of about 0.001 wt % to about 5 wt % based on 100 wt % of the semiconductor photoresist composition.

7. The semiconductor photoresist composition as claimed in claim 1, wherein:
the organometallic compound is in an amount of about 0.5 wt % to about 30 wt % based on 100 wt % of the semiconductor photoresist composition.

8. The semiconductor photoresist composition as claimed in claim 1, further comprising:
an additive of a surfactant, a crosslinking agent, a leveling agent, an organic acid, a quencher, or a combination thereof.

9. The semiconductor photoresist composition as claimed in claim 1, wherein:
the organometallic compound is an organotin compound comprising at least one selected from among an organic oxy group and an organic carbonyloxy group.

10. The semiconductor photoresist composition as claimed in claim 1, wherein:
the organometallic compound is represented by Chemical Formula 2: 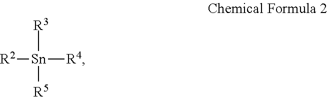
wherein, in Chemical Formula 2,
R² is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R³ to R⁵ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R³ to R⁵ is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

11. The semiconductor photoresist composition as claimed in claim 10, wherein:
at least one selected from among R³ to R⁵ is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

12. The semiconductor photoresist composition as claimed in claim 11, wherein:
R² is a substituted or unsubstituted C1 to C8 alkyl group, a substituted or unsubstituted C3 to C8 cycloalkyl group, a substituted or unsubstituted C2 to C8 unsaturated aliphatic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

13. The semiconductor photoresist composition as claimed in claim 1, wherein:
the organometallic compound is represented by Chemical Formula 3 or Chemical Formula 4: 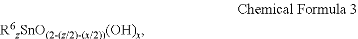
wherein, in Chemical Formula 3,
R⁶ is a C1 to C31 hydrocarbyl group, 0<z≤2, and 0<(z+x)≤4; 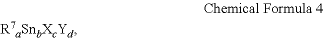
wherein, in Chemical Formula 4,
R⁷ is a substituted or unsubstituted C1 to C20 alkyl group, a substituted or unsubstituted C3 to C20 cycloalkyl group, a substituted or unsubstituted C2 to C20 unsaturated aliphatic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te), and
Y is —OR^{m} or —OC(═O)Rⁿ, and
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

14. A method, comprising:
forming an etching-objective layer on a substrate;
coating the semiconductor photoresist composition as claimed in claim 1 on the etching-objective layer to form a photoresist film;
patterning the photoresist film to form a photoresist pattern; and
etching the etching-objective layer utilizing the photoresist pattern as an etching mask,
wherein the method is a method of forming patterns.
